(19) United States
(12) Patent Application Publication
(10) Pub. No.: US 2014/0146446 A1
(43) Pub. Date: May 29, 2014

(54) Electronic Device

(71) Applicant: Kabushiki Kaisha Toshiba, Tokyo (JP)

(72) Inventors: Kyohei Matsuda, Ome-shi (JP); Yukihiro Suda, Tachikawa-shi (JP)

(73) Assignee: KABUSHIKI KAISHA TOSHIBA, Tokyo (JP)

(21) Appl. No.: 13/951,176

(22) Filed: Jul. 25, 2013

(30) Foreign Application Priority Data
Nov. 27, 2012 (JP) 2012-258886

(51) Int. Cl. H05K 5/02

(52) U.S. Cl. CPC H05K 5/02
USPC 361/679.01

(57) ABSTRACT

According to one embodiment, an electronic device includes a display device, a touch sensor, a housing, and a motion sensor. The display device includes a display screen. The touch sensor is configured to detect an operation performed at a display screen side of the display device. The housing includes a first end and a second end. The first end is positioned at a periphery side of the display screen and configured to be supported by a support. The second end is positioned at the periphery side of the display screen and at a side opposite the first end. The housing is configured to support the display device in a manner so that the display screen is viewable. The housing is configured to house an electrical component. The motion sensor is provided in the housing at a position closer to the first end than to the second end.

### CROSS-REFERENCE TO RELATED APPLICATIONS

This application is based upon and claims the benefit of priority from Japanese Patent Application No. 2012-258886, filed Nov. 27, 2012, the entire contents of which are incorporated herein by reference.

### FIELD

Embodiments described herein relate generally to an electronic device.

### BACKGROUND

Conventionally, there is known an electronic device provided with a motion sensor in a housing thereof.

For such electronic device, it is preferred to prevent unintended operations based on detection of a motion sensor.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view of an electronic device according to a first embodiment;

FIG. 2 is an exemplary side view of the electronic device in the first embodiment;

FIG. 3 is an exemplary schematic diagram of an internal configuration of the electronic device in the first embodiment;

FIG. 4 is an exemplary perspective view of a support that supports the electronic device in the first embodiment;

FIG. 5 is an exemplary front view illustrating a state in which the electronic device is supported by the support, in the first embodiment;

FIG. 6 is an exemplary control block diagram of the electronic device in the first embodiment;

FIG. 7 is an exemplary view illustrating a state in which an electronic device is held with a hand, according to a second embodiment;

FIG. 8 is an exemplary perspective view of a portion of the electronic device in the second embodiment;

FIG. 9 is an exemplary side view of an electronic device according to a third embodiment;

FIG. 10 is an exemplary perspective view of an electronic device as viewed from front according to a fourth embodiment;

FIG. 11 is an exemplary perspective view of the electronic device as viewed from behind in the fourth embodiment;

FIG. 12 is an exemplary side view of an electronic device according to a fifth embodiment;

FIG. 13 is an exemplary perspective view of an electronic device in a first position and a second position, as viewed from the front, according to a sixth embodiment;

FIG. 14 is an exemplary perspective view of the electronic device in a third position, as viewed from the front, in the sixth embodiment; and

FIG. 15 is an exemplary perspective view of the electronic device in the first position, as viewed from the back, in the sixth embodiment.

### DETAILED DESCRIPTION

In general, according to one embodiment, an electronic device includes a display device, a touch sensor, a housing, and a motion sensor. The display device includes a display screen. The touch sensor is configured to detect an operation performed at a display screen side of the display device. The housing includes a first end and a second end. The first end is positioned at a periphery side of the display screen and configured to be supported by a support. The second end is positioned at the periphery side of the display screen and at a side opposite the first end. The housing is configured to support the display device in a manner so that the display screen is viewable. The housing is configured to house an electrical component. The motion sensor is provided in the housing at a position closer to the first end than to the second end.

Exemplary embodiments and modifications described below comprise like components. In the description below, like components are denoted by common reference numerals, and a repetitive explanation thereof will be partially omitted.

While an electronic device is embodied as a personal computer in the embodiments and the modifications below, for example, an electronic device according to the present embodiment is not limited thereto. The electronic device according to the present embodiment may be embodied as various electronic devices, such as a smartphone, a mobile phone, a personal digital assistant (PDA), an electronic dictionary, a video display device, a video-phone, and a display device comprising a soft keyboard.

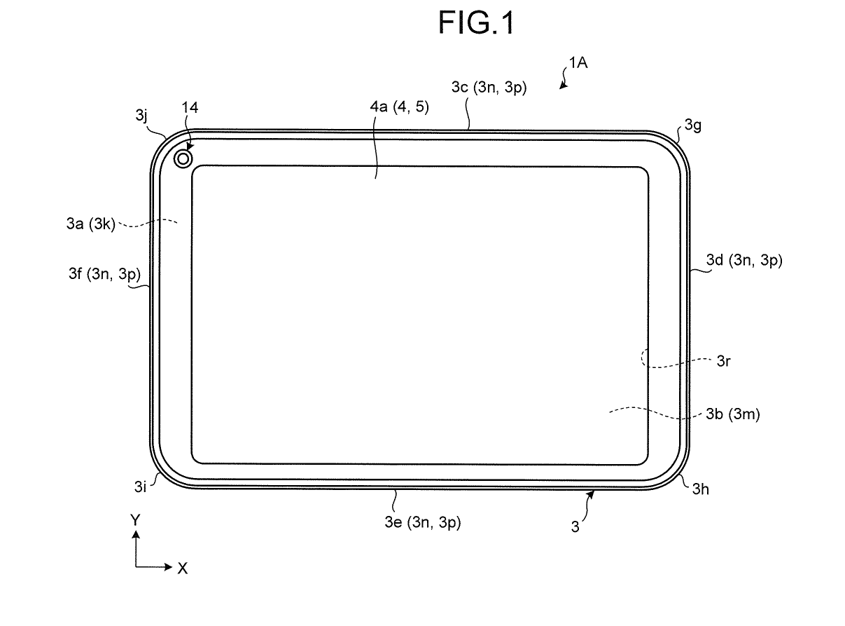

FIGS. 1 to 3 illustrate directions (an X-direction, a Y-direction, and Z-direction) for convenience. The X-direction represents a longitudinal direction with respect to a display screen 4a viewed from the front. The Y-direction represents a lateral direction with respect to the display screen 4a viewed from the front. The Z-direction represents a forward direction with respect to the display screen 4a (a thickness direction of a housing 3) viewed from the front. The X-direction, the Y-direction, and the Z-direction are orthogonal to one another.

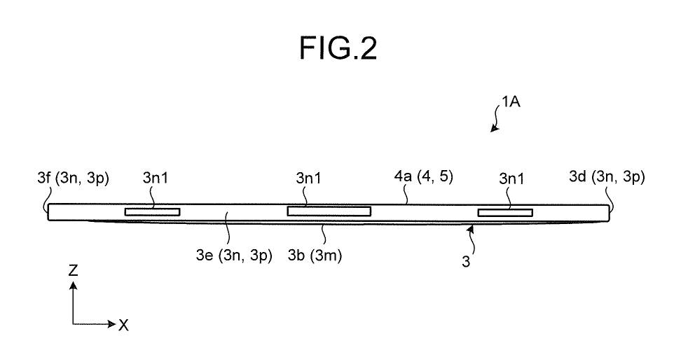

In a first embodiment, as illustrated in FIGS. 1, 2, and 5, and other drawings, the housing 3 of an electronic device 1A has an exterior appearance of a square shape (a rectangular shape in the first embodiment, for example) viewed from the front and the back, for example. The housing 3 is formed in a flat rectangular parallelepiped shape that has a small width in the front-back direction (the thickness direction of the housing 3 or the Z-direction). The housing 3 comprises a surface 3a (a face, a front surface, a surface, or a surface portion) and a surface 3b (a back surface, a rear surface, a reverse surface, or a surface portion) opposite thereto. The surface 3a and the surface 3b are provided in a manner facing opposite directions (parallel to each other in the first embodiment, for example). The housing 3 comprises four ends 3c to 3f (sides or edges) and four corners 3g to 3j (peaks, curves, or ends) viewed from the front. The ends 3c and 3e are examples of a long side. The ends 3d and 3f are examples of a short side. The housing 3 further comprises four surfaces 3p (side surfaces or surface portions) extending between the surface 3a and the surface 3b. The surfaces 3p need not be distinctly divided and may be smoothly connected with a curved portion, for example. In the description below, the upper side in FIG. 2 (normal direction of the display screen 4a) is represented by the front side, and the lower side in FIG. 2 (side opposite to the front side) is represented by the back side for convenience.

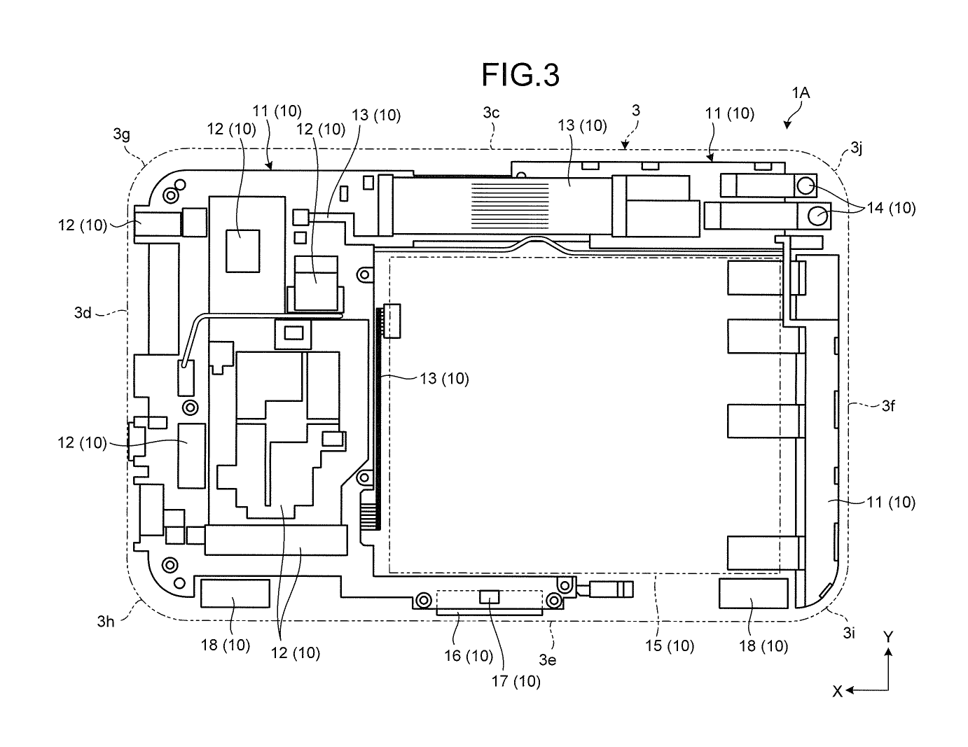

The housing 3 further comprises a wall 3k (a part, a plate, a frame, a front wall, a face wall, or a top wall) positioned at the front side and a wall 3m (a part, a plate, a rear wall, a back wall, or a bottom wall) positioned at the back side. The walls 3k and 3m are in a square shape (a rectangular shape in the first embodiment, for example). The wall 3k has an opening 3r in a square shape. Therefore, the wall 3k is formed in a square frame shape. The display screen 4a of a display device 4 is covered with a transparent portion of a touch panel 5 (a touch sensor or an input operation panel). The display screen 4a can be seen through the opening 3r. The wall 3k surrounds the display device 4. The wall 3m is formed in a square plate shape. The wall 3m covers a rear surface (not illustrated) positioned opposite the display screen 4a of the display device 4. The housing 3 further comprises four walls 3n (parts, plates, side walls, end walls, standing walls, or extending parts) extending between the wall 3k and the wall 3m. The walls 3n intersect with the wall 3m and extend along the side surface (not illustrated) of the display device 4 to cover the side surface. The wall 3m and the walls 3n need not be distinctly divided and may be smoothly connected with a curved portion, for example. The section of the connection between the wall 3m and the wall 3n may be formed in a seamless arc. The wall 3k and the walls 3n also need not be distinctly divided and may be smoothly connected with a curved portion, for example. The section of the connection between the wall 3k and the wall 3n may also be formed in a seamless arc. As illustrated in FIG. 2, the walls 3n have openings 3n1 through which a connector and a switch (an operating module) are exposed, for example. In the first embodiment, for example, the opening 3n1 positioned in the middle among the three openings 3n1 illustrated in FIG. 2 is used for a connector 16 (a second connector, refer to FIG. 3). The openings 3n1 positioned on both sides are used for speaker modules 18. The walls 3k and 3m extend nearly along the XY-plane. The housing 3 may comprise a wall (a part, a plate, a frame, a middle wall, an inner wall, a middle plate, a middle frame, or a third wall, which is not illustrated) positioned between the wall 3k and the wall 3m.

In the first embodiment, the housing 3 can be formed by combining a plurality of members (housing members, components, or divided parts), for example. The members constituting the housing 3 may be made of a synthetic resin material (e.g., plastic and engineering plastic) and a metal material (e.g., an aluminum alloy, a magnesium alloy, and a stainless steel), for example.

In the first embodiment, the housing 3 houses at least a portion of the display device 4 (a display module, a display, a panel, or a display component), for example. A user can see the display screen 4a from the front side (fore side) through the opening 3r. The display device 4 has an exterior appearance in a square shape (a rectangular shape in the first embodiment, for example) as viewed from the front. The display device 4 is formed in a flat rectangular parallelepiped shape that has a small width in the front-back direction (the Z-direction or the thickness direction of the housing 3). The display device 4 is a liquid crystal display (LCD) or an organic electro-luminescent display (OELD), for example. The display device 4 may be a flexible display. The touch panel 5 may be configured as an in-cell touch panel incorporated in the display device 4.

In the first embodiment, as illustrated in FIG. 3, the housing 3 houses electrical components 10 (components) on the rear side (the other side, the back side, the wall 3m side, or the side opposite the display screen 4a) of the display device 4, for example. Examples of the electrical components 10 include a circuit board 11 (a board, a printed circuit board, or a control board), a wire 13 (a cable, a harness, a flexible cable, or a flexible printed wiring board), a camera module 14 (a camera unit, a camera assembly, a camera, or an image capturing device), a battery module 15 (a battery, an assembled battery, a cell, a module, a battery pack, or a battery unit), the connector 16 (a connector unit, a connector assembly, a connector module, a connector device, a connection module, or a connecting module), a motion sensor 17 (a motion sensor module or a motion detector), and the speaker module 18 (a speaker unit, a speaker assembly, a speaker, or an audio output device). These electrical components are electrically connected to one another via the wire 13. The housing 3 may also house a vibration generator (e.g., a motor obtained by attaching an eccentric weight to a rotating shaft), which is not illustrated, for example. Various components 12 (electronic components, elements, chips, or packages) are provided to (mounted on) the circuit board 11 as the electrical components 10.

In the first embodiment, the battery module 15 may be configured as a lithium-ion secondary battery, for example. In the first embodiment, the battery module 15 can supply electric power required for the electronic device 1A to perform operations, such as displaying of video and outputting of audio, to the electrical components provided in the housing 3 besides to the display device 4 via the wire 13, for example. The battery module 15 can also supply electric power to an external device electrically connected to the circuit board 11 via the wire 13, a conductor (a bus bar, which is not illustrated), and the connector 16, for example. In the first embodiment, the battery module 15 has an exterior appearance in a square shape when viewed from the front and the back and has a flat shape with a small width in the thickness direction of the housing 3, for example. In the first embodiment, the battery module 15 is provided at a position closer to the end 3e than to the end 3c, for example.

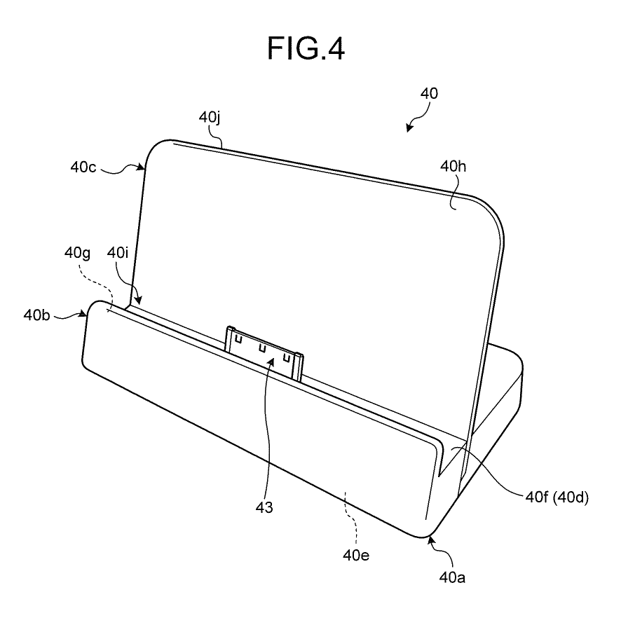

In the first embodiment, the connector 16 is electrically connected to another connector module (e.g., a connector 43 of a stand 40, refer to FIG. 4) to establish an electrical connection with an external electronic device, for example. The connector 16 is provided close to the end 3e in the housing 3. In the first embodiment, the connector 16 is provided to (mounted on) the circuit board 11, for example. The circuit board 11 provided with the connector 16 and the circuit board 11 provided with the other components 12 may be configured separately.

In the first embodiment, the motion sensor 17 may be configured as an acceleration sensor, an angular acceleration sensor, a tilt sensor, a vibration sensor, or a six-axis sensor, for example. The motion sensor 17 can detect a change in the posture and the position (e.g., movement, linear movement, tilting, and rotation) of the housing 3. In the first embodiment, the motion sensor 17 is provided close to the end 3e in the housing 3, for example. The motion sensor 17 is provided at a position closer to the end 3e than to the end 3c. In the first embodiment, the motion sensor 17 is provided to (mounted on) the circuit board 11 provided with the connector 16, for example. In the first embodiment, the motion sensor 17 is provided to the rear side of (the side opposite to) the connector 16, for example. In this case, the motion sensor 17 overlaps with the connector 16 in the thickness direction of the housing 3.

In the first embodiment, two speaker modules 18 are positioned close to the end 3e in the housing 3, for example. The two speaker modules 18 are provided at positions closer to the corners 3h and 3i than to the center (middle) of the end 3e. The two speaker modules 18 are positioned away from the motion sensor 17.

In the first embodiment, the circuit board 11 can be equipped with the components 12, such as a central processing unit (CPU), a graphic controller, a power circuit component, a platform controller hub (PCH), a memory slot connector, an LCD connector, an input/output (I/O) connector, a power coil, an element, and a connector, for example.

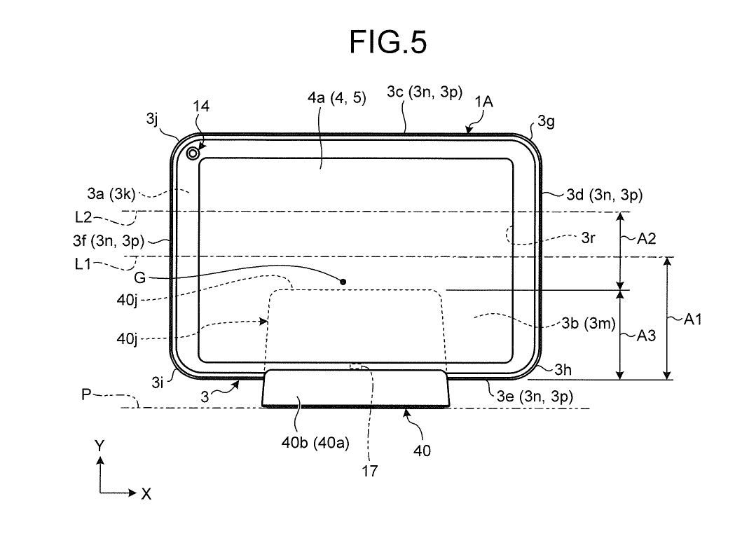

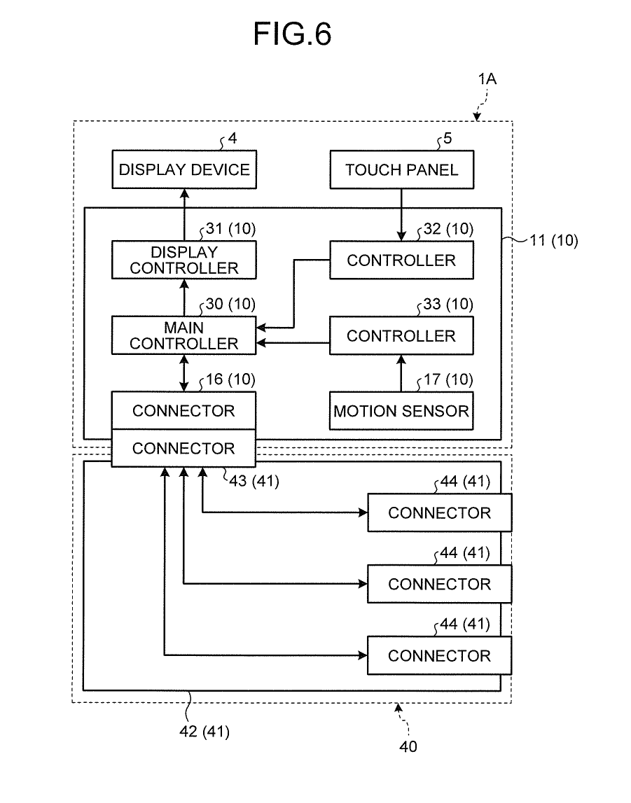

In the first embodiment, as illustrated in FIGS. 4 and 5, the electronic device 1A is supported by the stand 40 (a support, an expansion device, a dock, a docking station, or a cradle) in an attachable and detachable manner, for example. The stand 40 comprises a base 40a and walls 40b and 40c. The base 40a comprises walls 40d and 40e. When the stand 40 is placed on a placing surface P (a flat surface, refer to FIG. 5), the wall 40e faces (is opposed to) the placing surface P. The wall 40d and the wall 40e intersect with a normal direction (an orthogonal direction) of the placing surface P and are arranged with a gap interposed therebetween. In the first embodiment, the wall 40d, the wall 40e, and the placing surface P are nearly parallel to one another, for example. A space is formed between the wall 40d and the wall 40e. The space houses components 41 (electrical components, see FIG. 6), such as a circuit board 42. The wall 40b and the wall 40c are parallel to each other and extend in a direction intersecting with the placing surface P and inclined with respect to the normal direction of the placing surface P. The wall 40b, the wall 40d, and the wall 40c form a recess 40i (a housing portion or a groove) surrounded by the walls in nearly a U-shape. In the first embodiment, the middle portion of the end 3e in the longitudinal direction of the housing 3 of the electronic device 1A is inserted into the recess 40i, whereby the housing 3 is supported by the stand 40, for example. In the state illustrated in FIG. 5, the end 3e of the housing 3 comes into contact with a surface 40f (an upper surface, a top surface, or a surface) of the wall 40d. Thus, the wall 40d is an example of a support, and the end 3e is an example of a first end (a supported portion) in the first embodiment. Furthermore, in the state illustrated in FIG. 5, the electronic device 1A is supported by the stand 40 with the display screen 4a inclined backward. As a result, the wall 3m of the housing 3 comes into contact with a surface 40h (a front surface, a face, or a surface) of the wall 40c or with an end 40j of the wall 40c on the side away from the wall 40d. Thus, the wall 40c is an example of the support or a second support. Furthermore, in the state illustrated in FIG. 5, the end 3e of the housing 3 can come into contact with a surface 40g (a rear surface, a back surface, or a reverse surface) of the wall 40b. In this case, the wall 40b is an example of the support or the second support.

In the first embodiment, as illustrated in FIG. 4, the connector 43 (a connector unit, a connector assembly, a connector module, a connector device, a connection module, or a connecting module) protrudes from the wall 40d in the recess 40i, for example. In the state illustrated in FIG. 5, the connector 43 enters into the housing 3 through the opening 3n1 (see FIG. 2) provided to the wall 3n of the end 3e of the housing 3. As a result, the connector 43 and the connector 16 are connected to each other electrically and mechanically. In this state, electrodes (terminals or conductive modules, which are not illustrated) provided to the connector 16 and the connector 43 elastically come into contact with each other. As a result, the electrodes are electrically connected.

In the first embodiment, as illustrated in FIG. 6, the electronic device 1A comprises a main controller 30, the circuit board 11, a display controller 31, controllers 32 and 33, the display device 4, the touch panel 5, the connector 16, and the motion sensor 17, for example. The stand 40 comprises the circuit board 42, the connector 43, and connectors 44. In the example of FIG. 6, the connector 16 and the connector 43 are electrically connected, whereby a plurality of connectors 44 are electrically connected to the electronic device 1A. In other words, with the connector 43, no connector 44 needs to be provided to the electronic device 1A. Thus, the stand 40 also functions as a function expansion device for the electronic device 1A.

In the first embodiment, the display controller 31 controls the display device 4 such that a certain image is displayed on the display screen 4a, for example. The controller 32 inputs a control signal to the main controller 30 based on detection results of the touch panel 5. Based on the control signal received from the controller 32, the main controller 30 controls the display controller 31 to control an image to be displayed on the display screen 4a. Further, the controller 33 determines the direction of an image to be displayed on the display screen 4a of the display device 4 based on detection results of the motion sensor 17 and inputs a control signal to the main controller 30. Based on the control signal received from the controller 33, that is, based on the direction of the image determined by the controller 33, the main controller 30 controls the display controller 31 such that the image is displayed on the display screen 4a in a more appropriate state (e.g., a direction and a size). The controllers 32 and 33 may be configured as individual dedicated ICs or an integrated controller.

If an operator operates the touch panel 5 in the state illustrated in FIG. 5, the motion sensor 17 may possibly detect movement and vibration of the housing 3. In the electronic device 1A, if a physical quantity detected by the motion sensor 17 is larger than a predetermined threshold, the controller 33 inputs a control signal to the main controller 30. As a result, the load on the main controller 30 is likely to increase. Furthermore, depending on the supported posture of the electronic device 1A or if input (a pressing force) to the touch panel 5 is relatively large, for example, the direction and the size of the image on the display screen 4a may possibly change unintentionally. In other words, an operation of the motion sensor 17 may possibly cause a disadvantageous situation in the state illustrated in FIG. 5.

In this regard, in the first embodiment, the motion sensor 17 is positioned close to the end 3e (the first end or the supported portion) at which the housing 3 is supported by the stand 40, as illustrated in FIGS. 3 and 5 for example. Therefore, according to the first embodiment, a moment arm from a supporting point positioned at the end 3e side at which the stand 40 supports the housing 3 (e.g., the contact point between the wall 40d and the wall 3n) to the motion sensor 17 is made shorter, for example. As a result, movement of the motion sensor 17 is prevented, whereby the physical quantity detected by the motion sensor 17 is likely to decrease. Therefore, according to the first embodiment, occurrence of the disadvantageous situation described above can be prevented, for example.

While the motion sensor 17 is positioned close to the end 3e in the first embodiment, for example, similar advantageous effects can be achieved even if the motion sensor 17 is positioned at other positions. If the motion sensor 17 is provided at a position closer to the end 3e (the first end or the supported portion) than to the end 3c (a second end or an end away from the supported portion) in the front view with respect to the display screen 4a (that is, a position in an area A1 closer to the end 3e with respect to a middle line L1 between the end 3c and the end 3e in FIG. 5), for example, the moment arm from the supporting point at which the stand 40 supports the housing 3 (e.g., the contact point between the wall 40d and the wall 3n) to the motion sensor 17 is made shorter than that in the case where the motion sensor 17 is provided in an area closer to the end 3c with respect to the line L1. Therefore, occurrence of the disadvantageous situation described above can be prevented, for example.

If the housing 3 is supported at a supporting area (a supporting position) closer to the end 3c than to the end 3e by the wall 40c (second support) of the stand 40, for example, and if the motion sensor 17 is provided at a position closer to an end of the supporting area at the end 3c side (e.g., the end 40j of the wall 40c) than to the end 3c in the front view with respect to the display screen 4a (that is, a position in an area A2 closer to the end 40j with respect to a middle line L2 between the end 3c and the end 40j in FIG. 5), a moment arm from the supporting point at which the stand 40 supports the housing 3 (e.g., the contact point between the wall 40c and the wall 3m) to the motion sensor 17 is made shorter than that in the case where the motion sensor 17 is provided in an area closer to the end 3c with respect to the line L2. Therefore, occurrence of the disadvantageous situation described above can be prevented. Furthermore, in this configuration, even if the motion sensor 17 is provided at a position (in an area A3) between the end 3e and the end of the supporting area on the end 3c side (e.g., the end 40j of the wall 40c) in the front view, for example, movement of the motion sensor 17 is prevented. As a result, the physical quantity detected by the motion sensor 17 is likely to decrease. Therefore, occurrence of the disadvantageous situation described above can be prevented, for example.

In the first embodiment, as illustrated in FIG. 3, the connector 16 is provided close to the end 3e (closer to the end 3e than the end 3c), for example. The motion sensor 17 is provided close to the end 3e (closer to the end 3e than the end 3c). The stand 40 supports the end 3e. Therefore, according to the first embodiment, it is possible to achieve both the establishment of electrical connection between the electronic device 1A and the stand 40 via the connectors 16 and 43 and the prevention of movement of the motion sensor 17, for example.

In the first embodiment, as illustrated in FIG. 3, the motion sensor 17 and the connector 16 are provided to a single circuit board 11, for example. Therefore, the configuration of the device can be simplified compared with the case in which the motion sensor 17 and the connector 16 are provided to different circuit boards 11 separately, for example.

In the first embodiment, as illustrated in FIG. 1, the camera module 14 is provided close to the end 3c and the end 3f (a third end), that is, closer to the ends 3c and 3f than to the ends 3d and 3e, for example. The motion sensor 17 is provided closer to the ends 3d and 3e different from the ends 3c and 3f (closer to the ends 3d and 3e (to the end 3e in the first embodiment, for example) than to the ends 3c and 3f). The stand 40 supports the end 3e. Therefore, according to the first embodiment, it is possible to achieve both the prevention of interference of the camera module 14 with the stand 40 and the prevention of movement of the motion sensor 17, for example.

In the first embodiment, as illustrated in FIG. 3, the battery module 15 is provided close to the end 3e (closer to the end 3e than the end 3c) of the housing 3 of the electronic device 1A, for example. Because the weight of the battery module 15 is relatively large, the center of gravity G of the housing 3 (refer to FIG. 5) is located close to the center of gravity G of the battery module 15. As the motion sensor 17 is positioned away from the center of gravity G of the housing 3, movement of the motion sensor 17 is likely to increase. Therefore, according to the first embodiment, movement of the motion sensor 17 can be prevented, for example. Furthermore, in the first embodiment, the motion sensor 17 is provided at a position closer to the end 3e positioned close to the center of gravity G than to the end 3c positioned away from the center of gravity G, for example. Therefore, according to the first embodiment, movement of the motion sensor 17 can be prevented, for example. Moreover, in the first embodiment, the motion sensor 17 is provided at a position closer to the end 3e (the first end or the supported portion) than to the center of gravity G, for example. Therefore, according to the first embodiment, movement of the motion sensor 17 can be further prevented, for example.

In the first embodiment, the speaker modules 18 are positioned away from the motion sensor 17, for example. If the speaker modules 18 are positioned close to the motion sensor 17, vibration caused by audio output from the speaker modules 18 may possibly be detected by the motion sensor 17. In this regard, according to the first embodiment, movement of the motion sensor 17 can be prevented, for example.

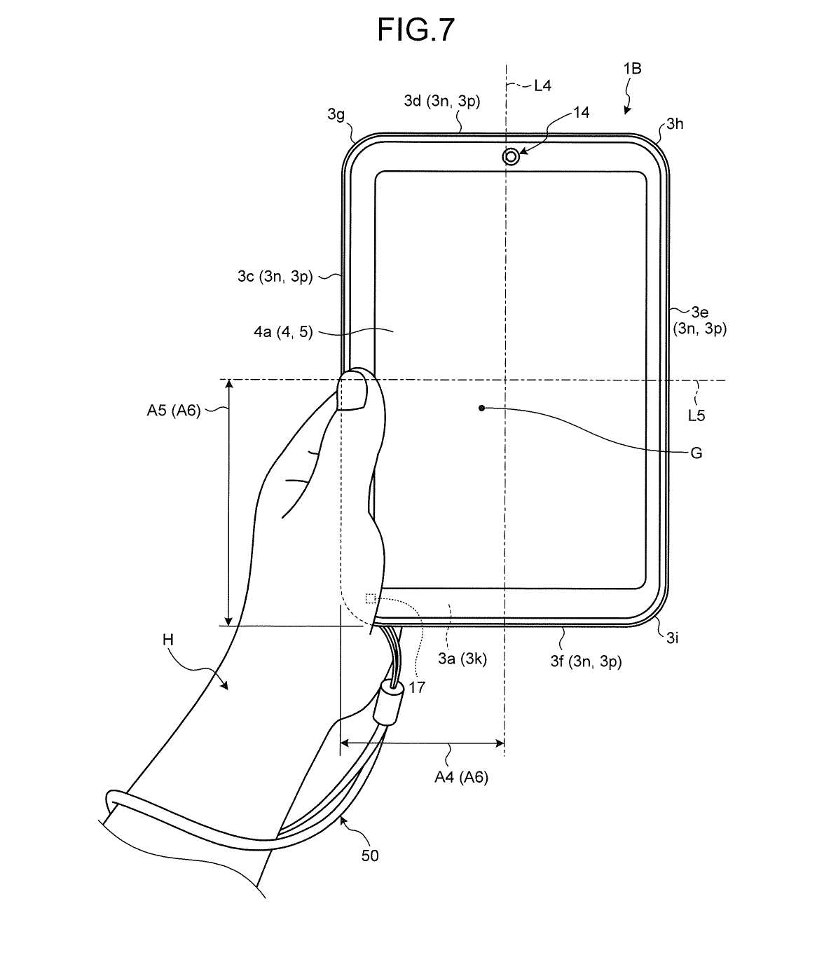

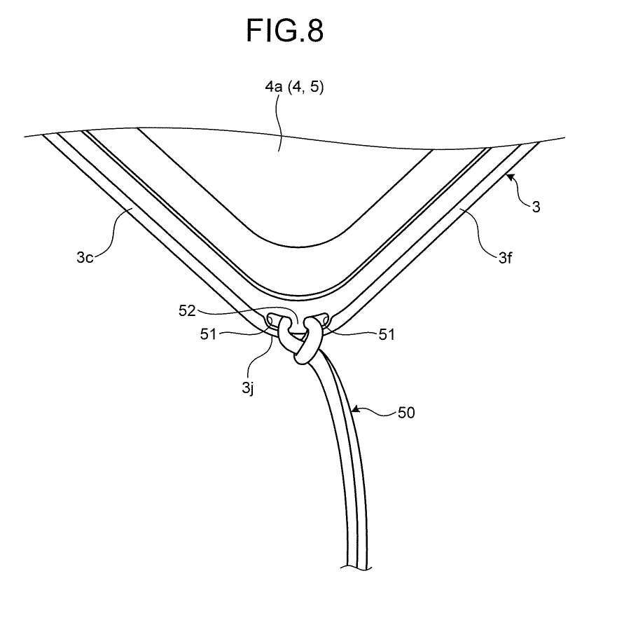

An electronic device 1B according to a second embodiment has a configuration similar to that of the first embodiment. Therefore, according to the second embodiment as well, similar advantageous results (effects) can be achieved based on the configuration similar to that of the first embodiment. In the second embodiment, however, a corner 3j (an end) of a housing 3 of the electronic device 1B has a strap hole 51 to which a strap 50 is attached as illustrated in FIGS. 7 and 8, for example. The strap hole 51 is a through hole passing through the space between an end 3c and an end 3f. The strap hole 51 provides the corner 3j with a brace 52 (a supported portion) extending in the thickness direction of the housing 3. In this configuration, as illustrated in FIG. 7, a user holds the corner 3j of the housing 3 close to the strap hole 51 or the end 3c or the end 3f adjacent to the corner 3j with a hand H. In other words, the corner 3j, the end 3c, and the end 3f of the housing 3 are examples of a portion supported by the hand H or the strap 50 (a grasped portion, a held portion, or a supported portion) and examples of a first end in the second embodiment. By contrast, a corner 3h, an end 3d, and an end 3e positioned on the side opposite the corner 3j, the end 3c, and the end 3f are examples of a second end (an end away from the supported portion). The strap 50 is an example of a support.

Therefore, in the second embodiment, if a motion sensor 17 is provided at a position closer to the end 3c than to the end 3e in the front view with respect to a display screen 4a (that is, a position in an area A4 closer to the end 3c with respect to a middle line L4 between the end 3c and the end 3e in FIG. 7), if the motion sensor 17 is provided at a position closer to the end 3f than to the end 3d (that is, a position in an area A5 closer to the end 3f with respect to a middle line L5 between the end 3d and the end 3f in FIG. 7), or if the motion sensor 17 is provided in an area closer to the end 3c with respect to the line L4 and closer to the end 3f with respect to the line L5 (that is, an area A6 where the area A4 and the area A5 overlap with each other), for example, a moment arm from the portion of the housing 3 supported by the hand H (e.g., the corner 3j, the end 3c, and the end 3f) to the motion sensor 17 is made shorter than that in the case where the motion sensor 17 is provided in an area on the side opposite thereto. Therefore, according to the second embodiment as well, occurrence of the disadvantageous situation described above can be prevented, for example. Furthermore, in the second embodiment as well, the motion sensor 17 is provided at a position closer to the ends 3c and 3f positioned close to the center of gravity G than to the ends 3d and 3e positioned away from the center of gravity G, for example. Therefore, according to the second embodiment, movement of the motion sensor 17 can be prevented, for example. Moreover, in the second embodiment as well, the motion sensor 17 is provided at a position closer to the corner 3j, the end 3c, or the end 3f (the first end or the supported portion) than to the center of gravity G, for example. Therefore, according to the second embodiment, movement of the motion sensor 17 can be further prevented, for example.

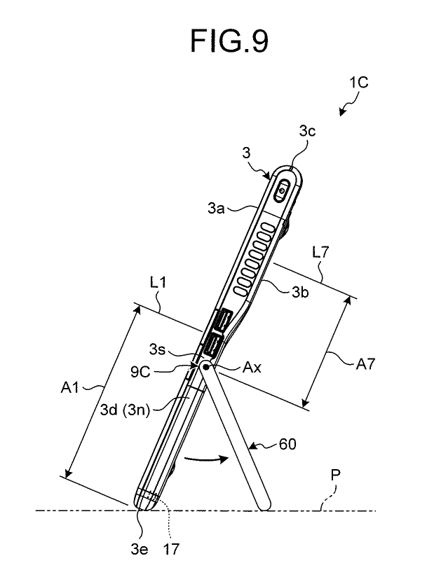

An electronic device 1C according to a third embodiment has a configuration similar to those of the first and the second embodiments. Therefore, according to the third embodiment as well, similar advantageous results (effects) can be achieved based on the configuration similar to those of the first and the second embodiments. In the third embodiment, however, a folding stand 60 (a second support) is connected to a housing 3 with a hinge 9C as illustrated in FIG. 9, for example. The stand 60 can rotate (can move) between a stored position along the housing 3 and an released position away from the housing 3. If the stand 60 is released as illustrated in FIG. 9, an end 3e of the housing 3 is supported in a manner so as to be placed (put) on the placing surface P, and a portion 3s (a supported portion) in the middle in the longitudinal direction of a wall 3n to which the hinge 9C is provided is supported by the stand 60. The portion 3s is positioned closer to an end 3e than to the end 3c. In the third embodiment, if a motion sensor 17 is provided at a position closer to the end 3e (a first end) than to the end 3c (a second end) in the front view with respect to a display screen 4a (that is, a position in an area A1 closer to the end 3e with respect to a middle line L1 between the end 3c and the end 3e), or if the motion sensor 17 is provided at a position closer to the portion 3s (hinge 9C) than to the end 3c (that is, a position in an area A7 closer to the hinge 9C with respect to a middle line L7 between the end 3c and the portion 3s), or if the motion sensor 17 is provided in the stand 60, for example, occurrence of the disadvantageous situation described above can be prevented.

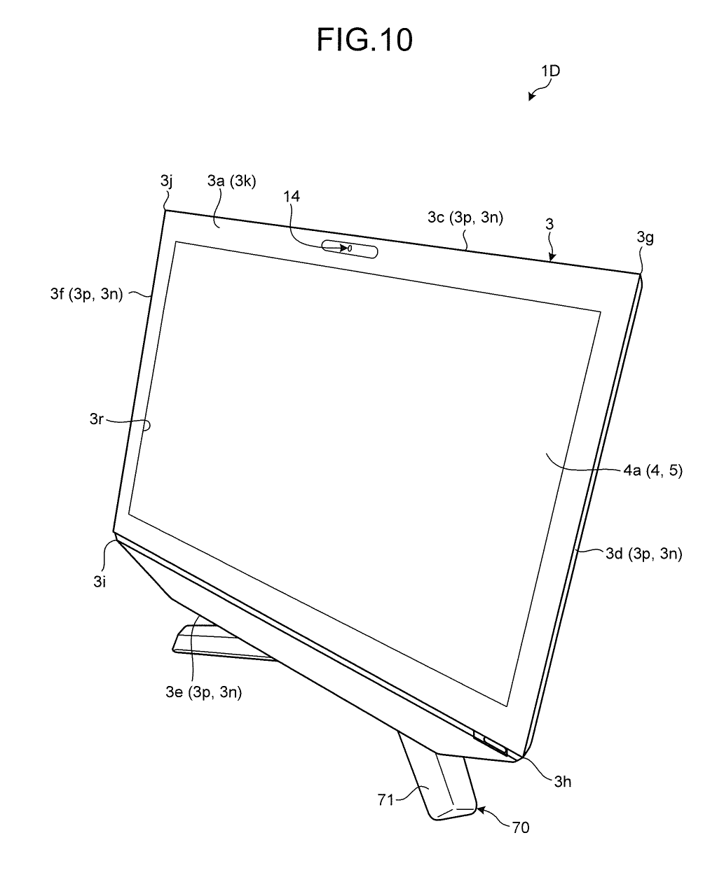

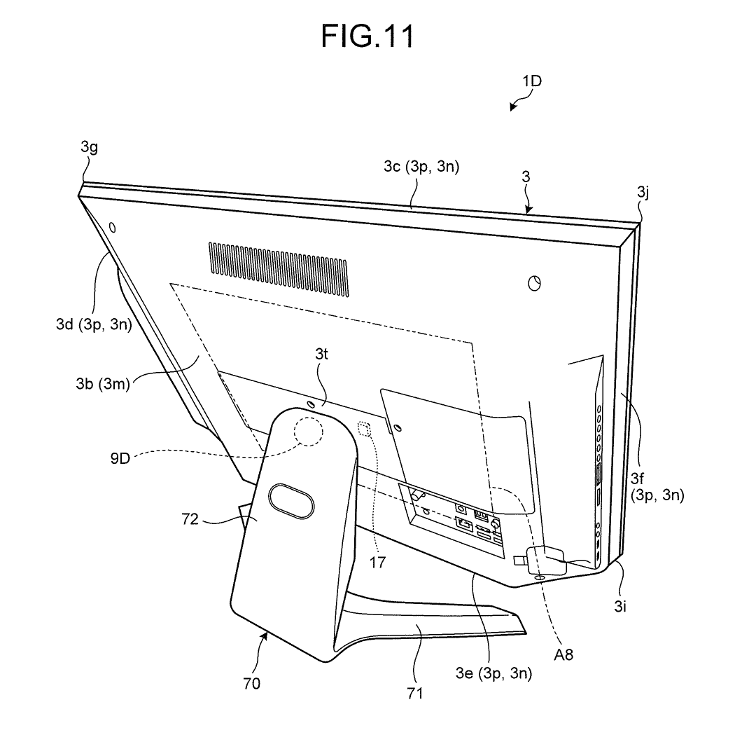

An electronic device 1D according to a fourth embodiment has a configuration similar to those of the first to the third embodiments. Therefore, according to the fourth embodiment as well, similar advantageous results (effects) can be achieved based on the configuration similar to those of the first to the third embodiments. In the fourth embodiment, however, a fixed stand 70 (a support, a leg, or an arm) is connected to a housing 3 with a hinge 9D as illustrated in FIGS. 10 and 11, for example. The stand 70 comprises a base 71 and an arm 72. The base 71 has an exterior appearance in a V-shape and is placed on a placing surface. The arm 72 protrudes from a corner of the V of the base 71. The tip of the arm 72 is connected to a portion 3t (a supported portion) at nearly the center of a wall 3m of the housing 3 in a rotatable manner with the hinge 9D. The hinge 9D enables the housing 3 to rotate three-dimensionally (e.g., pivoting, swiveling, and tilting). The hinge 9D may be configured as a ball joint to which rotational resistance torque (position holding torque for the housing 3) is applied, for example. In the fourth embodiment, if a motion sensor 17 is provided at a position closer to the supported portion 3t than to ends 3c to 3f (ends away from the supported portion 3t) in the front view with respect to a display screen 4a, that is, a position in an area A8 surrounded by a middle line between the portion 3t and each of the ends 3c to 3f, for example, occurrence of the disadvantageous situation described above can be prevented.

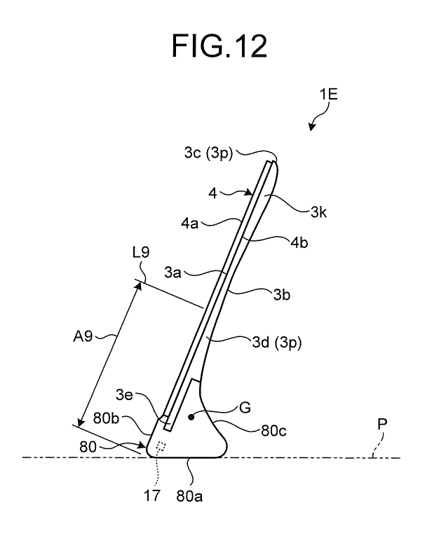

An electronic device 1E according to a fifth embodiment has a configuration similar to those of the first to the fourth embodiments. Therefore, according to the fifth embodiment as well, similar advantageous results (effects) can be achieved based on the configuration similar to those of the first to the fourth embodiments. In the fifth embodiment, however, a stand 80 (an extended portion, a thick portion, a part of a housing, or a supported portion) is provided adjacently to an end 3e of a housing 3 as illustrated in FIG. 12, for example. The thickness of the stand 80 increases toward the side opposite the end 3c side. The stand 80 comprises surfaces 80a, 80b, and 80c. The surface 80a (an end) is formed in a planer shape. The surface 80b is formed in a planar shape extending nearly along a display screen 4a. The surface 80c extends to a surface 3b of the housing 3 in a curve. The surface 80a make an acute angle with the surface 80b. The stand 80 houses a battery and a circuit board (neither of which is illustrated), for example. In the fifth embodiment, the center of gravity G of the electronic device 1E is positioned closer to the surface 80a than to the end 3c, for example. The electronic device 1E with this configuration can be stood with the surface 80a placed on the placing surface P as illustrated in FIG. 12. In the fifth embodiment, if a motion sensor 17 is provided at a position closer to the stand 80 (the surface 80a thereof, a first end, or a supported portion) than to the end 3c (an end away from the stand 80) in the front view with respect to the display screen 4a, that is, a position in an area A9 closer to the surface 80a with respect to a middle line L9 between the end 3c and the surface 80a, for example, occurrence of the disadvantageous situation described above can be prevented. Furthermore, in the fifth embodiment as well, the motion sensor 17 is provided at a position closer to the surface 80a serving as an end positioned close to the center of gravity G than to the end 3c positioned away from the center of gravity G, for example. Therefore, according to the fifth embodiment, movement of the motion sensor 17 can be prevented, for example. Moreover, in the fifth embodiment as well, the motion sensor 17 is provided at a position closer to the surface 80a (the first end or the supported portion) than to the center of gravity G, for example. Therefore, according to the fifth embodiment, movement of the motion sensor 17 can be further prevented, for example.

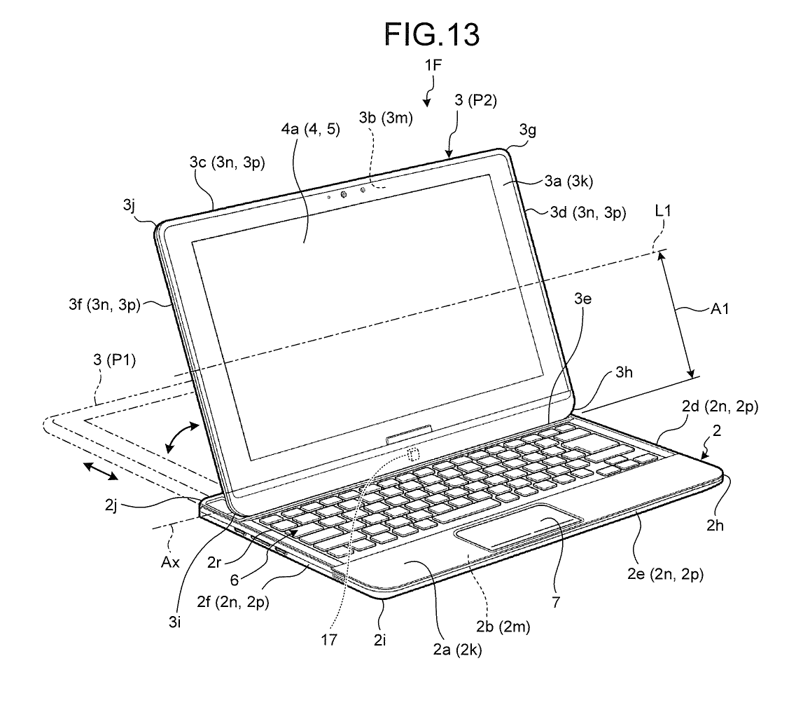

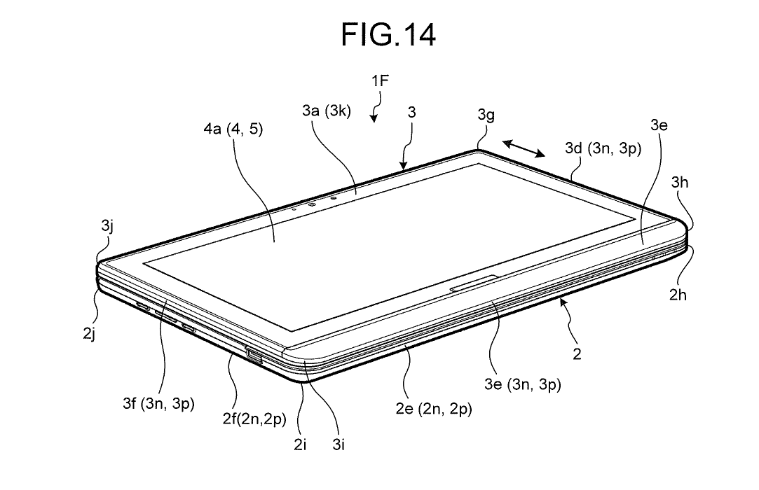

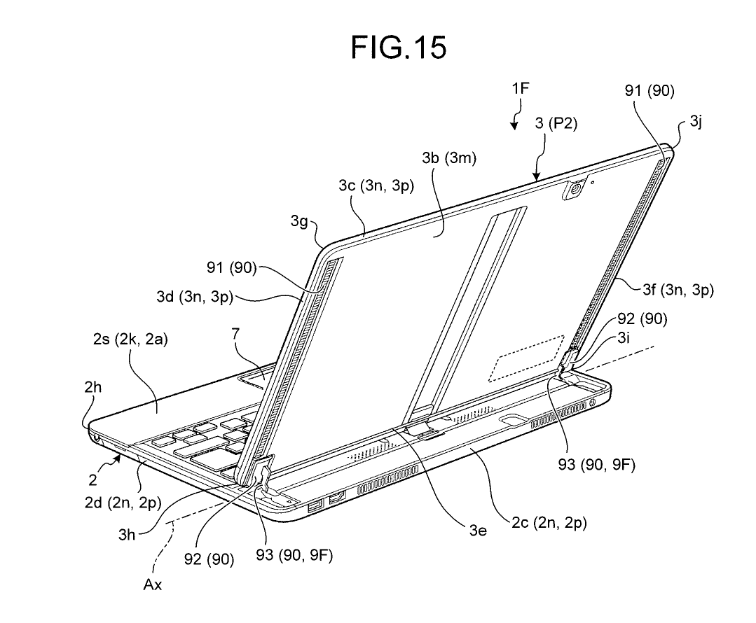

An electronic device 1F according to a sixth embodiment has a configuration similar to those of the first to the fifth embodiments. Therefore, according to the sixth embodiment as well, similar advantageous results (effects) can be achieved based on the configuration similar to those of the first to the fifth embodiments. In the sixth embodiment, however, the electronic device 1F comprises two housings 2 and 3 as illustrated in FIGS. 13 to 15, for example. The electronic device 1F can be used in a tablet mode (a slate mode, see FIG. 14) in which the two housings 2 and 3 overlap with each other in the thickness direction and a clamshell mode (a note mode, see FIGS. 13 and 15) in which the housing 2 and the housing 3 are connected in a rotatable manner with a hinge 9F (see FIG. 15).

In the sixth embodiment, the housings 2 and 3 are connected to each other with a movable mechanism 90 as illustrated in FIG. 15, for example. The movable mechanism 90 comprises a rail 91, a slider 92, and a link arm 93. The rails 91 extend along ends 3d and 3f on a wall 3m (a surface 3b) of the housing 3. The slider 92 is supported by the rail 91 in a reciprocable manner. The link arm 93 links the slider 92 and the housing 2 in a rotatable manner. A user slides the housing 3 along a surface 2a of the housing 2 from the tablet mode illustrated in FIG. 14. The user then stands the housing 3 thus slid on the housing 2 with the link arm 93 as illustrated in FIG. 15, thereby shifting the electronic device 1F to the clamshell mode. The electronic device 1F can also be used while maintaining the state of the housing 3 indicated by a dashed-two dotted line in FIG. 13.

The housing 2 has an appearance in a square shape (a rectangular shape in the sixth embodiment, for example) as viewed from front and behind, for example. The housing 2 is formed in a flat rectangular parallelepiped shape that has a small width in the front-back direction (the thickness direction of the housing 2). The housing 2 comprises the surface 2a (a face, a front surface, a surface, or a surface portion) and a surface 2b (a back surface, a rear surface, a reverse surface, or a surface portion) opposite thereto. The surface 2a and the surface 2b are provided in a manner facing opposite directions (parallel to each other in the sixth embodiment, for example). The housing 2 comprises four ends 2c to 2f (sides or edges) and four corners 2g to 2j (peaks, curves, or ends) when viewed from the front. The ends 2c and 2e are examples of a long side. The ends 2d and 2f are examples of a short side. The housing 2 further comprises four surfaces 2p (side surfaces or surface portions) extending between the surface 2a and the surface 2b. The surfaces 2p need not be distinctly divided and may be smoothly connected with a curved portion, for example.

The housing 2 further comprises a wall 2k (a part, a plate, a frame, a front wall, a face wall, or a top wall) positioned at the front side and a wall 2m (a part, a plate, a rear wall, a back wall, or a bottom wall) positioned at the back side. The walls 2k and 2m are in a square shape (a rectangular shape in the sixth embodiment, for example). The wall 2k has an opening 2r in a square shape. A keyboard module 6 (an input operating module, an input receiving module, or an input module) is exposed through the opening 2r. The wall 2k surrounds the keyboard module 6. The wall 2m is formed in a square plate shape. The wall 2k is further provided with a pointing device 7 (a touch pad, an input operating module, an input receiving module, or an input module).

The housing 2 further comprises four walls 2n (parts, plates, side walls, end walls, standing walls, or extending parts) extending between the wall 2k and the wall 2m. The walls 2n extend between the wall 2k and the wall 2m in a manner intersecting therewith. The wall 2m and the walls 2n need not be distinctly divided and may be smoothly connected with a curved portion, for example. The section of the connection between the wall 2m and the wall 2n may be formed in a seamless arc. The wall 2k and the walls 2n also need not be distinctly divided and may be smoothly connected with a curved portion, for example. The section of the connection between the wall 2k and the wall 2n may also be formed in a seamless arc. In the sixth embodiment, the housing 2 can be formed by combining a plurality of members (housing members, components, or divided parts), for example. The members constituting the housing 2 may be made of a synthetic resin material (e.g., plastic and engineering plastic) and a metal material (e.g., an aluminum alloy, a magnesium alloy, and a stainless steel), for example.

In the clamshell mode illustrated in FIGS. 13 and 15, the housing 2 functions as an example of a support. Therefore, in the sixth embodiment as well, if a motion sensor 17 is provided at a position closer to the end 3e (a first end) than the end 3c (a second end) in the front view with respect to a display screen 4a (that is, a position in an area A1 closer to the end 3e with respect to a middle line L1 between the end 3c and the end 3e) or if the motion sensor 17 is provided in the housing 2 serving as an example of the support, for example, occurrence of the disadvantageous situation described above can be prevented.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a display device comprising a display screen;
a touch sensor configured to detect an operation performed at a display screen side of the display device;
a housing comprising a first end and a second end, the first end being positioned at a periphery side of the display screen and configured to be supported by a support, the second end being positioned at the periphery side of the display screen and at a side opposite the first end, the housing being configured to support the display device in a manner so that the display screen is viewable, the housing being configured to house an electrical component; and
a motion sensor provided in the housing at a position closer to the first end than to the second end.

2. The electronic device of claim 1, wherein
the support comprises a first connector, and
the housing is provided with a second connector positioned close to the first end and configured to be electrically connected to the first connector.

3. The electronic device of claim 2, further comprising a circuit board provided with the motion sensor and the second connector.

4. The electronic device of claim 1, wherein
a portion of the housing on a side closer to the second end than to the first end is configured to be supported by a second support, and
the motion sensor is provided at a position closer to the second support than to the second end.

5. The electronic device of claim 1, further comprising a camera module, wherein
the housing comprises a third end to which the camera module is provided, positioned at the periphery side of the display screen, and different from the first end.

6. The electronic device of claim 1, further comprising a battery module provided at a position closer to the first end than to the second end.

7. The electronic device of claim 1, further comprising a speaker module positioned away from the motion sensor.

8. The electronic device of claim 1, wherein the first end is provided with a strap hole at the first end.

9. An electronic device comprising:
a display device;
a housing comprising a first end and a second end, the first end being supported by a support, the second end being positioned opposite the first end, the housing being configured to support the display device; and
a motion sensor provided in the housing at a position closer to the first end than to the second end.

10. An electronic device comprising:
a display device;
a housing comprising a portion supported by a support and an end positioned away from the supported portion, the housing being configured to support the display device; and
a motion sensor provided in the housing at a position closer to the supported portion than to the end.
